(19) United States
(12) Patent Application Publication
(10) Pub. No.: US 2013/0100603 A1
(43) Pub. Date: Apr. 25, 2013

(54) ELECTRONIC DEVICE WITH MULTI-ROUTES FOR INTERFACE

(71) Applicant: MIAO HE, Shenzhen City (CN)

(72) Inventor: MIAO HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/284,999

(22) Filed: Oct. 31, 2011

(30) Foreign Application Priority Data
Oct. 21, 2011 (CN) 201110322689.6

(51) Int. Cl. G06F 1/16; H05K 7/02

(52) U.S. Cl. 361/679.32; 361/807; 361/811

(57) ABSTRACT

An electronic device includes a processing unit, a first connection element, a first interface group which includes at least one interface, a second connection element, and a second interface group which includes a number of interfaces. The first connection element is detachably connected between the processing unit and the first interface group. The second connection element is detachably connected between the processing unit and the second interface group and the user can select between the two elements.

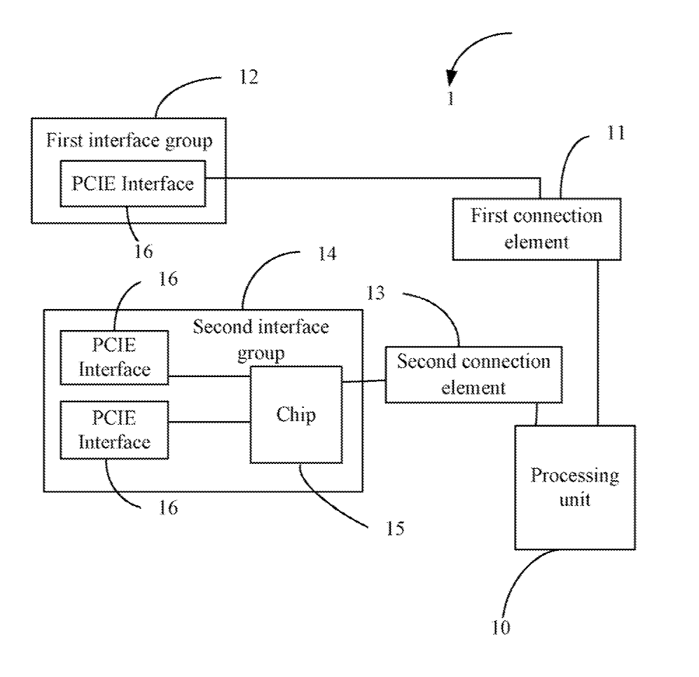

### BACKGROUND

1. Technical Field

The present disclosure relates to an electronic device with multi-routes for interfaces.

2. Description of Related Art

In some low-end electronic devices, only one data interface is provided. In some high-end electronic devices, an interface chip with a number of data interfaces are provided. But if the user wants to have a number of data interfaces available, the only way is to buy a high-end electronic device, which may not be economical for the user.

### BRIEF DESCRIPTION OF THE DRAWINGS

The components of the drawing are not necessarily drawn to scale, the emphasis instead being placed upon clearly illustrating the principles of the present disclosure.

The FIGURE is a block diagram of an electronic device with multi-routes for interfaces in one exemplary embodiment.

### DETAILED DESCRIPTION

Referring to the FIGURE, an electronic device 1 includes a processing unit 10, a first connection element 11, a first interface group 12, a second connection element 13, and a second interface group 14. The first connection element 11 is detachably connected between the processing unit 10 and the first interface group 12 to form a first route. The second connection element 13 is detachably connected between the processing unit 10 and the second interface group 14 to form a second route. In this embodiment, the first interface group 12 includes one interface 16. The second interface group 14 includes a chip 15 and a number of interfaces 16.

When the interface 16 in the first route is selected to be used, the first connection element 11 is set to the first route to connect the processing unit 10 and the first interface group 12, the second connection element 13 is detached from the second route by the user to cut the connection between the processing unit 10 and the second interface group 14. When the interfaces 16 in the second route is selected to be used, the second connection element 13 is set to the second route to connect the processing unit 10 and the second interface group 14, and the first connection element 11 is detached by the user from the first route to cut the connection between the processing unit 10 and the first interface group 12. Accordingly, the user can select the interface in a different route to use.

In this embodiment, the first connection element 11 is a resistor and the second connection element 13 is a capacitor. The interface 16 is a peripheral component interface express (PCIE) interface.

Although the present disclosure has been specifically described on the basis of exemplary embodiments, the disclosure is not to be construed as being limited thereto. Various changes or modifications may be made to the embodiment without departing from the scope and spirit of the disclosure.

What is claimed is:

1. An electronic device comprising:
a processing unit, a first connection element, a first interface group which comprises at least one interface, a second connection element, and a second interface group which comprises a plurality of interfaces, wherein the first connection element is detachably connected between the processing unit and the first interface group; and the second connection element is detachably connected between the processing unit and the second interface group.

2. The electronic device as described in claim 1, wherein the first interface group comprises one interface.

3. The electronic device as described in claim 1, wherein the second interface group comprises a chip and a plurality of interfaces.

4. The electronic device as described in claim 1, wherein the first connection element is a resistor and the second connection element is a capacitor.

5. The electronic device as described in claim 1, wherein the at least one interface comprised in the first interface group and the plurality of interfaces comprised in the second interface group are peripheral component interface express (PCIE) interfaces.
